(19) United States
(12) Patent Application Publication
(10) Pub. No.: US 2008/0067058 A1
(43) Pub. Date: Mar. 20, 2008

(54) MONOLITHIC TARGET FOR FLAT PANEL APPLICATION

(76) Inventors: BRADLEY O. STIMSON, Monte Sereno, CA (US); Akihiro Hosokawa, Cupertino, CA (US); Makoto Inagawa, Palo Alto, CA (US)

Correspondence Address: PATTERSON & SHERIDAN, LLP, 3040 POST OAK BOULEVARD, SUITE 1500, HOUSTON, TX, 77056, US

(21) Appl. No.: 11/852,136

(22) Filed: Sep. 7, 2007

Related U.S. Application Data
(60) Provisional application No. 60/825,775, filed on Sep. 15, 2006.

(51) Int. Cl. C23C 14/14; C23C 14/34

(52) U.S. Cl. 204/192.15; 204/192.12; 204/298.12; 204/298.13

(57) ABSTRACT

The present invention generally comprises a monolithic sputtering target assembly for depositing material onto large area substrates. The sputtering target assembly may comprise both the sputtering target and the backing plate in one monolithic structure. By having the backing plate and sputtering target as a monolithic structure, bonding is not necessary. Additionally, cooling channels may be drilled into the monolithic structure so that cooling fluid may flow within the sputtering target assembly without the need for a separate cooling assembly resting on back of the sputtering target assembly.

### CROSS-REFERENCE TO RELATED APPLICATIONS

This application claims benefit of U.S. provisional patent application Ser. No. 60/825,775 (APPM/011515L), filed Sep. 15, 2006, which is herein incorporated by reference.

### BACKGROUND OF THE INVENTION

1. Field of the Invention

Embodiments of the present invention generally relate to a monolithic sputtering target assembly for depositing material onto large area substrates.

2. Description of the Related Art

Physical Vapor Deposition (PVD) using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (i.e., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

Large area sputtering targets are necessary for depositing material onto large area substrates such as flat panel display substrates, solar panel substrates, and other large area substrates. As the size of the substrate increases, so must the sputtering target. Producing large area sputtering targets that may provide a uniform deposition and consistent film characteristics is a challenge. It would be beneficial to produce a large area sputtering target suitable for depositing material onto large area substrates while also maintaining film uniformity and consistent characteristics throughout the film at a reasonable cost. Therefore, there is a need in the art for a large area sputtering target.

### SUMMARY OF THE INVENTION

The present invention generally comprises a monolithic sputtering target assembly for depositing material onto large area substrates. The sputtering target assembly may comprise both the sputtering target and the backing plate in one monolithic structure. By having the backing plate and sputtering target as a monolithic structure, bonding is not necessary. Additionally, cooling channels may be drilled into the monolithic structure so that cooling fluid may flow within the sputtering target assembly without the need for a separate cooling assembly resting on back of the sputtering target assembly.

In one embodiment, a monolithic target assembly is disclosed. The assembly comprises sputtering target and a backing plate wherein one or more cooling channels are bored into the monolithic body.

In another embodiment, a sputtering apparatus is disclosed. The sputtering apparatus comprises a vacuum chamber, a susceptor, a monolithic target assembly positioned in the vacuum chamber, and one or more anodes extending across the vacuum chamber in an area between the susceptor and the sputtering target assembly. The assembly comprises a sputtering target and a backing plate wherein one or more cooling channels are bored into the monolithic body.

In still another embodiment, a method is disclosed. The method comprises positioning a monolithic target assembly in a vacuum chamber and sputtering material from the assembly onto a substrate. The assembly comprises a sputtering target and a backing plate, wherein one or more cooling channels are bored into the monolithic body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-section view of a PVD apparatus 100 according to one embodiment of the invention.

FIG. 2 is an exploded orthographic view of a two-dimensional scan mechanism 200 according to one embodiment of the invention.

FIG. 3 is a plan view of a rectangular spiral magnetron 300.

FIG. 4A is a cross sectional view of a monolithic sputtering target assembly 400 according to one embodiment of the invention.

FIG. 4B is a cross sectional view of a monolithic sputtering target assembly 410 according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a monolithic sputtering target assembly for depositing material onto large area substrates. The sputtering target assembly may comprise both the sputtering target and the backing plate in one monolithic structure. By having the backing plate and sputtering target as a monolithic structure, bonding is not necessary. Additionally, cooling channels may be drilled into the monolithic structure so that cooling fluid may flow within the sputtering target assembly without the need for a separate cooling assembly resting on back of the sputtering target assembly.

The invention is illustratively described and may be used in a PVD system for processing large area substrates, such as a PVD system, available from AKT, a subsidiary of Applied Materials, Inc., Santa Clara, Calif. However, it should be understood that the sputtering target may have utility in other system configurations, including those systems configured to process large area round substrates. An exemplary system in which the present invention can be practiced is described in U.S. patent application Ser. No. 11/225,922, filed Sep. 13, 2005, which is hereby incorporated by reference in its entirety.

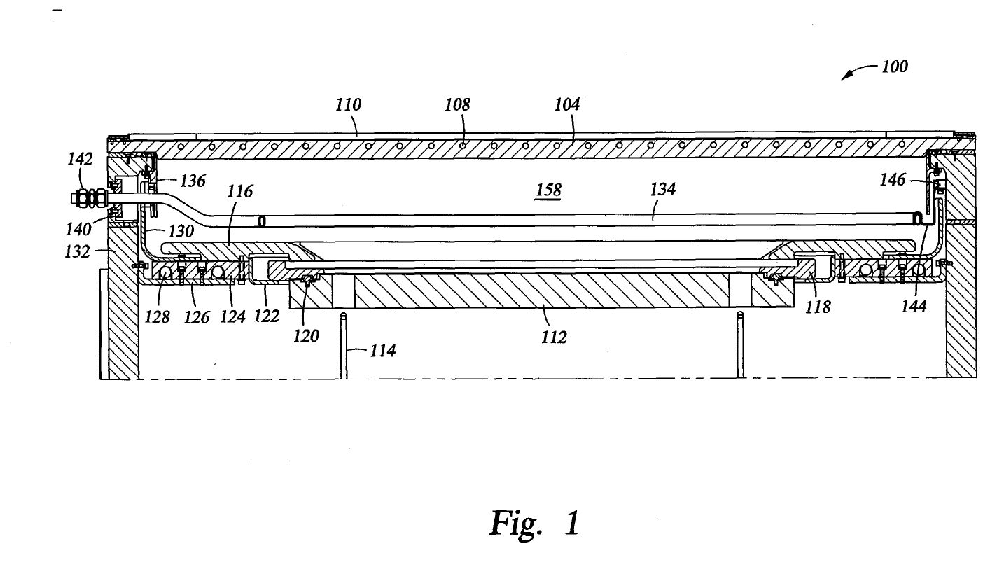

FIG. 1 is a cross-section view of a PVD apparatus 100 according to one embodiment of the invention. The apparatus 100 includes a monolithic sputtering target assembly 104. The monolithic target assembly 104, as described below, combines a backing plate and a sputtering target into a single, monolithic structure. In one embodiment, the target assembly 104 comprises aluminum. In another embodiment, the target assembly 104 comprises aluminum and niobium. The target assembly 104 sits opposite a susceptor 112 across a processing space 158. Within the target assembly 104 are cooling channels 108 that may provide a uniform temperature across the target assembly 104. A dark space shield 136 surrounds the target assembly 104. A magnetron 110 may be present behind the backing plate.

Electrons within the sputtering plasma are attracted to elements within the apparatus 100 that are grounded. Traditionally, the chamber walls 132 and the susceptor 112 or substrate support are grounded and thus, function as an anode in opposition to the sputtering target assembly 104, which functions as the cathode.

The grounded chamber walls 132 functioning as an anode attract electrons from the plasma and hence, may tend to create a higher density of plasma near the chamber walls 132. A higher density of plasma near the chamber walls 132 may increase the deposition on the substrate near the chamber walls 132 and decrease the deposition away from the chamber walls 132. The grounded susceptor 112, on the other hand, also functions as an anode. The susceptor 112 may span a significant length of the processing space 158. Thus, the susceptor 112 may provide a path to ground for electrons not only at the edge of the susceptor 112, but also at the middle of the susceptor 112. The path to ground at the middle of the susceptor 112 balances out the path to ground at the edge of the susceptor 112 and the chamber walls 132 because each anode, be it the chamber walls 132 or the susceptor 112, will equally function as an anode and uniformly spread the plasma across the processing space 158. By uniformly distributing the plasma across the processing space 158, uniform deposition across the substrate may occur.

When the substrate is an insulating substrate (such as glass or polymer), the substrate is non-conductive and thus electrons do not follow through the substrate. As a consequence, when the substrate substantially covers the substrate support, the substrate support does not provide sufficient anode surfaces. For large area substrates, such as solar panels or substrates for flat panel displays, the size of the substrate blocking the path to ground through the susceptor 112 may be significant. Substrates as large as 1 meter by 1 meter are not uncommon in the flat panel display industry. For a 1 meter by 1 meter substrate, a path to ground through the susceptor 112 is blocked for an area of 1 square meter. Therefore, the chamber walls 132 and the edges of the susceptor 112 that are not covered by the substrate are the only paths to ground for the electrons in the plasma. With a large area substrate, a high density plasma may form near the chamber walls 132 and the edge of the susceptor 112 that are not covered by the substrate. The high density plasma near the chamber walls 132 and the susceptor 112 edge may thin the plasma near the center of the processing region 158 where no path to ground exists. Without a path to ground near the center of the processing area 158, the plasma may not be uniform and hence, the deposition on the large area substrate may not be uniform.

An anode 134 may be placed between the target assembly 104 and a substrate (not shown) to help provide uniform sputtering deposition across the substrate. In one embodiment, the anode is bead blasted stainless steel coated with arc sprayed aluminum. In one embodiment, one end of the anode 134 may be mounted to the chamber wall 132 by a bracket 144 which may be coupled with a mounting ledge 146. As shown in FIG. 1, a portion of the bracket 144 lies between the dark space shield 136 and the chamber shield 130.

The other end of the anode 134 passes through the dark space shield 136 and the chamber wall 132. At the end of the anode 134 is a connection assembly 142. The connection assembly 142 may be any conventionally known device for connecting fluid containing tubes together. An additional bracket 140 may couple the anode 134 to the chamber wall 132 and stabilize the connection assembly 142. In another embodiment, the anode 134 may be mounted with an anchor mount, which may be shielded from deposition by an anode shield. The anchor mount may be positioned on the shield 116.

The anode 134 provides a charge in opposition to the target assembly 104 so that charged ions will be attracted thereto rather than to the chamber walls 132 which are typically at ground potential. By providing the anode 134 between the target assembly 104 and the substrate, the plasma may be more uniform, which may aid in the deposition. In one embodiment, six anodes are positioned between the target assembly 104 and the substrate. Exemplary anodes that may be used to practice the invention are disclosed in U.S. patent application Ser. No. 11/182,034, filed Jul. 13, 2005, U.S. patent application Ser. No. 11/247,705, filed Oct. 11, 2005, and U.S. patent application Ser. No. 11/247,438, filed Oct. 11, 2005, each of which is hereby incorporated by reference in their entirety.

When a substrate enters the apparatus 100, lift pins 114 rise up to receive the substrate. The lift pins 114 then lower and the susceptor 112 raises to receive the substrate. As the susceptor 112 raises to a processing position, the susceptor 112 encounters the shadow frame 118 and raises the shadow frame 118 up to a processing position with shadow frame lift pins 120. The shadow frame 118 reduces the amount of material that may deposit on exposed areas of the susceptor 112. When not raised, the shadow frame 120 rests on an under shield 122. The under shield 122 may be coupled with a cooling manifold 124.

Because the shadow frame 122 moves up and down, any material that deposits on the shadow frame 122 may flake off. To reduce flaking of material from the shadow frame 122, an additional shield 116, which is stationary, may be positioned within the apparatus 100 to shield the shadow frame 122. Shield 116 is coupled with the cooling manifold 124. The cooling manifold 124 controls the temperature of the shield 116. Expansion and contraction of the shield 116 from temperature changes may cause flaking within the apparatus 100 and contaminate the substrate. By controlling the temperature of the shield 116, expansion and contraction of the shield 116 may be reduced. The cooling manifold 124 rests on a manifold shelf 126 and may be cooled by a cooling fluid that passes through cooling channels 128. The cooling fluid may be any conventional cooling fluid known to one of ordinary skill in the art. Similar reasoning applies to the anode 134. In one embodiment, the anode 134 may be cooled.

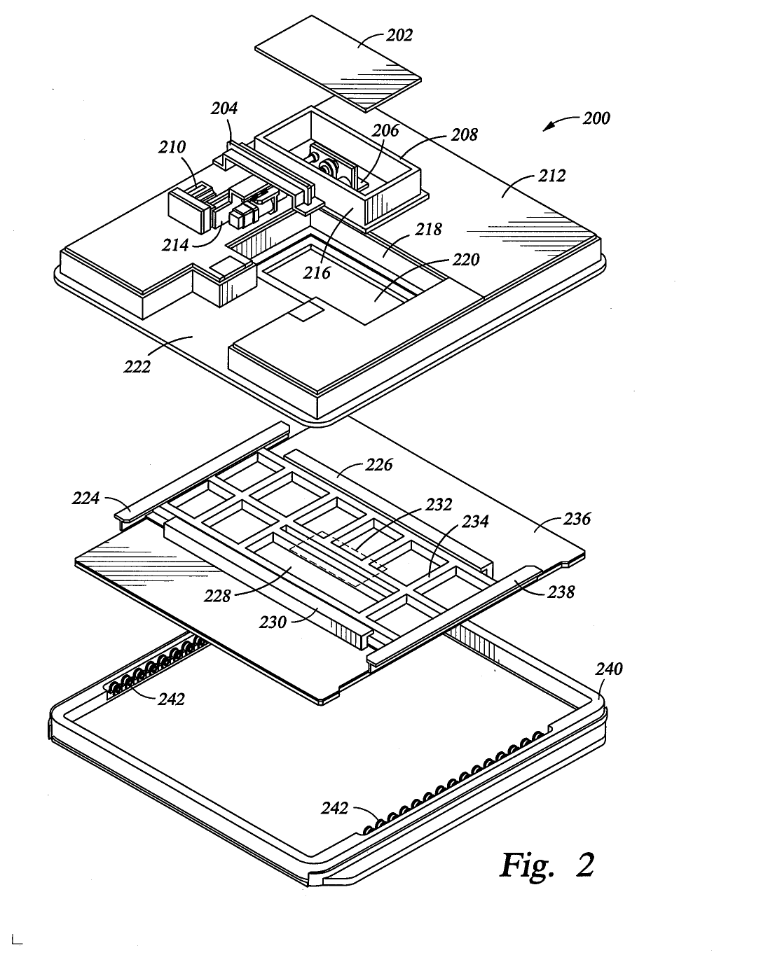

The magnetron 110 may be scanned across the back of the target assembly 104 by a scanning mechanism 200. FIG. 2 is an exploded orthographic view of a two-dimensional scan mechanism 200 according to one embodiment of the invention. The scanning mechanism 200 may comprise a frame 240 having two or more rows of rollers 242 that rollably support inverted frame rails 224, 238. The inverted frame rails 224, 238 support a gantry 234 between them. The gantry 234 may include a hole 228 and two or more rows of rollers (not shown) for rollably supporting inverted gantry rails 226, 230, from which the magnetron plate 236 depends through fixed connections. By rolling motion of the gantry 234 and the rails 224, 226, 230, 238, the magnetron plate 236 may move in perpendicular directions inside the frame 240 to scan the magnetic field across the target assembly. A base plate 232 may be fixed to the frame structure that forms the gantry 234.

A magnet chamber roof 212 may be supported on and sealed to the frame 240 with the gantry structure disposed therebetween. The magnet chamber roof 212 may include a rectangular aperture 220, an actuator recess 222, and a bracket recess 218. A bracket chamber 208 may fit within the bracket recess and be sealed to the chamber roof 212 around the rectangular aperture 220. The bracket chamber 208 may comprise sidewalls 216 and a top plate 202. Within the bracket chamber 208, the gantry bracket 206 may be housed. An actuator assembly 210 may be held in the actuator recess 222 by an angle iron 214 and a support bracket 204. In one embodiment, the magnetron may be scanned in a serpentine pattern across the back of the sputtering target assembly. In another embodiment, the magnetron may rest on roller balls and springs as described in U.S. patent application Ser. No. 11/347,667, filed Feb. 3, 2006 which is hereby incorporated by reference in its entirety.

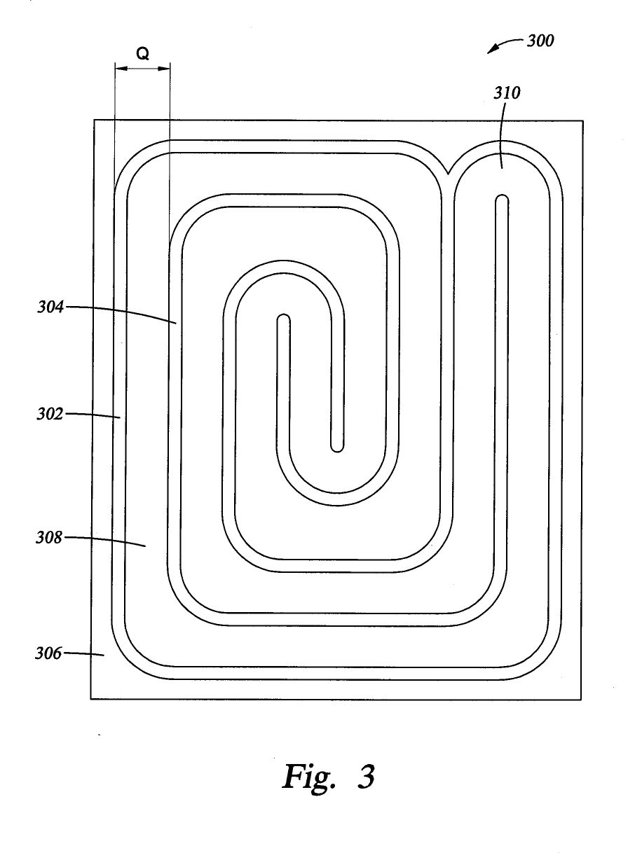

The magnetron may have various shapes. FIG. 3 is a plan view of a rectangular spiral magnetron 300 according to one embodiment of the invention. The magnetron 300 includes a non-magnetic magnetron plate 306, and a plurality of magnet tracks 302, 304. In one embodiment, the magnet track 302 may have a curved portion 310. The area between the magnet tracks 302, 304 is referred to as a mesa 308. The mesa 308 may have a pitch of Q. In one embodiment, the magnet tracks 302, 304 may be electromagnets. In another embodiment, the magnet tracks 302, 304 may be permanent magnets. In yet another embodiment, the magnet tracks 302, 304 may each comprise a plurality of permanent magnets. The magnetron confines the high density plasma generated within the vacuum chamber to a specific area on the target surface. By scanning the magnetron across the back of the monolithic target assembly, the magnetic field confining the plasma scans across the front surface of the monolithic target assembly and hence, may create a more uniform erosion of target material from the monolithic target assembly.

There are many benefits to using a monolithic target assembly. When using a monolithic sputtering target assembly, no delamination of the sputtering target from the backing plate may occur because a separate backing plate and target are not present. Without a separate backing plate and target, no bonding is present. When a separate sputtering target and backing plate are used, the backing plate may sometimes warp. Additionally, any cooling channels within the backing plate may occasionally need to be repolished to ensure that the cooling fluid continues to flow through the cooling channels at the desired flow rate. When warping occurs or repolishing is necessary, the backing plate may need to be refurbished.

A monolithic sputtering target may increase sputtering efficiency over a sputtering target and backing plate bonded together. In a monolithic sputtering target, the backing plate and the sputtering target are the same material without a bonding layer therebetween. Therefore, the heat transfer coefficient for the backing plate and the sputtering target is identical. Additionally, the backing plate and the sputtering target in a monolithic sputtering target would have the same conductivity. Thus, an applied current would follow through the sputtering target assembly in an efficient manner as compared to a current that travels through a backing plate, bonding material, and the sputtering target. Therefore, due to the same heat transfer coefficient and conductivity, the monolithic sputtering target may have a higher sputtering efficiency than a sputtering target bonded to a backing plate.

When refurbishing a backing plate or a sputtering target, the target and the backing plate may be debonded so that any warping of the backing plate may be corrected. For large area sputtering target assemblies (i.e., an area greater than about 1 or 2 square meters), the backing plate and the target may need to be transported to another location for the refurbishing and/or debonding. Because the target and backing plate have a large area, it may not simply be a matter of loading the target and backing plate onto a truck and transporting it. The target and backing plate may need to be transported as an “oversized load” and thus necessitate a road escort. At the very least, there are transportation costs, refurbishing costs, debonding costs, and re-bonding costs associated with a large area target assembly comprising a separate backing plate and target.

A monolithic target assembly, on the other hand, is beneficial because there is no backing plate to warp. Should any warping occur or should the target erode to the point where it is no longer useable, the assembly may simply be scrapped and replaced instead of refurbishing it. This is particularly true with aluminum monolithic sputtering target assemblies because aluminum is well known to be recyclable. The aluminum monolithic sputtering target assembly may be simply cut down to an appropriate size for transportation while on site at the production facility and then transported to an aluminum recycle center where it may be sold. While transportation costs are incurred, the need for an “oversized load” escort may be eliminated.

The costs associated with a monolithic sputtering target assembly represent a savings over a sputtering target with backing plate assembly. For example, to bond the sputtering target to the backing plate, a bonding material is necessary. Thus, bonding costs are present for the material and labor costs are necessary to bond the target to the backing plate. With a monolithic sputtering target assembly, the target and backing plate are integrated in a monolithic structure, so that the target and backing plate need not be bonded to each other because they are a single, monolithic piece. Therefore, the monolithic sputtering target assembly does not have bonding, or as necessary, debonding costs. The overall cost per substrate, when factoring in transportation, refurbishing, bonding, debonding, recycling, etc., may be lowered by using a monolithic sputtering target assembly as opposed to a traditional target bonded to backing plate assembly.

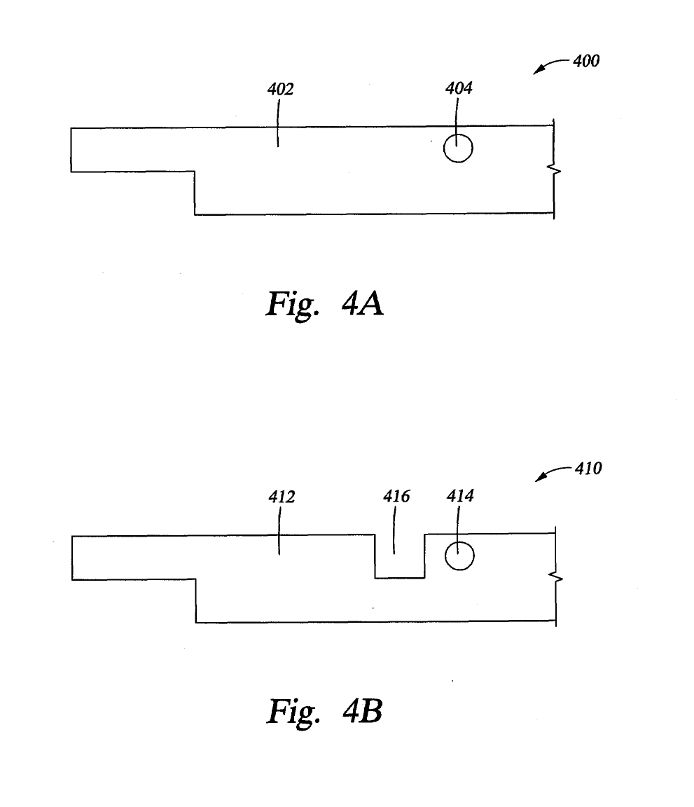

FIG. 4A is a cross sectional view of a monolithic sputtering target assembly 400 according to one embodiment of the invention. The monolithic target assembly 400 includes a monolithic target 402 having one or more cooling channels 404 drilled into the target assembly 400. Cooling fluid may flow through the cooling channels to provide a uniform temperature to the target assembly 400. Any conventionally known cooling fluid may be utilized.

FIG. 4B is a cross sectional view of a monolithic sputtering target assembly 410 according to another embodiment of the invention. The monolithic target assembly 410 includes a monolithic target 412 having one or more cooling channels 414 drilled into the target assembly 410. A groove 416 may be machined into the target assembly 410 to reduce the weight of the target assembly 416. As discussed in Ser. No. 11/483,134, filed Jul. 7, 2006 and hereby incorporated by reference in its entirety, the groove 416 may be filled with a polymer material to lessen the weight of the target assembly 410, if desired, and provide a flat surface upon which a magnetron assembly may move.

Monolithic sputtering target assemblies may produce films with consistent characteristics throughout the deposited layer. Because the target is monolithic, the composition and grain structure of the material sputtered may be uniform throughout the sputtering target and hence, the deposited layer. Due to the uniform composition and grain structure, erosion from the sputtering target during sputtering may be more uniform. Monolithic sputtering target assemblies are cost effective for depositing films having uniform composition and grain structure onto large area substrates.

While the foregoing is directed to embodiments of the present invention, other and further embodiments of the invention may be devised without departing from the basic scope thereof, and the scope thereof is determined by the claims that follow.

1. A monolithic target assembly, comprising:
a sputtering target; and
a backing plate, wherein one or more cooling channels are bored into the monolithic target assembly.

2. The target assembly of claim 1, wherein the assembly comprises aluminum.

3. The target assembly of claim 2, wherein the assembly comprises aluminum and niobium.

4. The target assembly of claim 1, further comprising:
channels carved into the assembly, the channels carved into spaces between adjacent cooling channels.

5. The target assembly of claim 1, wherein the assembly is shaped such that an edge portion of the target assembly is thinner than a middle portion.

6. The target assembly of claim 1, wherein the assembly has an area greater than about 1 square meter.

7. A sputtering apparatus, comprising:
a vacuum chamber;
a susceptor;
a monolithic target assembly positioned in the vacuum chamber, the assembly comprising:
a sputtering target; and
a backing plate, wherein one or more cooling channels are bored into the monolithic target assembly; and
one or more anodes extending across the vacuum chamber in an area between the susceptor and the sputtering target assembly.

8. The apparatus of claim 7, wherein the assembly comprises aluminum.

9. The apparatus of claim 8, wherein the assembly comprises aluminum and niobium.

10. The apparatus of claim 7, further comprising:
channels carved into the assembly, the channels carved into spaces between adjacent cooling channels.

11. The apparatus of claim 7, wherein the assembly is shaped such that an edge portion of the target assembly is thinner than a middle portion.

12. The apparatus of claim 7, wherein the vacuum chamber comprises a plurality of chamber walls, the assembly resting on at least a portion of at least one chamber wall.

13. The apparatus of claim 7, wherein the assembly has an area of greater than about 1 square meter.

14. A method, comprising:
positioning a monolithic target assembly in a vacuum chamber, the monolithic target assembly comprising:
a sputtering target; and
a backing plate, wherein one or more cooling channels are bored into the monolithic target assembly; and
sputtering material from the assembly onto a substrate.

15. The method of claim 14, further comprising:
flowing a cooling fluid through at least one cooling channel bored into the assembly.

16. The method of claim 14, wherein the assembly has an area greater than about 1 square meter.

17. The method of claim 14, further comprising:
performing said sputtering a plurality of times prior to recycling said assembly; and
recycling said assembly.

18. The method of claim 14, wherein said assembly comprises aluminum

19. The method of claim 18, wherein said assembly comprises aluminum and niobium.

20. The method of claim 14, moving a magnetron in a serpentine pattern across a back surface of the assembly.
